(19) United States
(12) Patent Application Publication
(10) Pub. No.: US 2026/0136884 A1
(43) Pub. Date: May 14, 2026

(54) APPARATUS AND METHOD FOR TESTING FRAME FORM PLASMA PROCESS

(71) Applicant: TAIWAN SEMICONDUCTOR MANUFACTURING COMPANY, LTD., Hsinchu (TW)

(72) Inventors: Yun-Fang WU, Hsinchu (TW); Yi Chen HO, Taichung (TW)

(21) Appl. No.: 18/940,984

(22) Filed: Nov. 8, 2024

(51) Int. Cl. H01L 21/683; H01L 21/02; H01L 21/66

(52) U.S. Cl. CPC H10P 72/722; H10P 14/6528; H10P 74/203

(57) ABSTRACT

Embodiments of the present disclosure provide a method that includes providing a plasma chamber including an electrostatic chuck and a frame receiving unit configured to support and position a frame with respect to the electrostatic chuck, wherein the electrostatic chuck is configured to receive, at different times, the frame or a wafer without the frame, positioning the wafer onto the electrostatic chuck without the frame, performing the activation process on a front side of the wafer, determining, based on one or more measurements, whether the activation process performed on the wafer using the plasma chamber satisfies a performance threshold, positioning the frame, including a plurality of semiconductor dies disposed thereon, onto the electrostatic chuck, and performing, based on determining that the activation process satisfies the performance threshold, plasma processing on a front side of the plurality of semiconductor dies.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate views of various stages of a chip on wafer semiconductor packaging process, in accordance with some embodiments.

FIG. 2 is a flowchart that illustrates a method for a chip on wafer semiconductor packaging process, in accordance with some embodiments.

FIG. 3 illustrates views of various stages of testing a frame form plasma process, in accordance with some embodiments.

FIG. 4 is a flowchart that illustrates a method for testing a frame form plasma process, in accordance with some embodiments.

FIG. 5 illustrates views of various stages and associated components for adapting an electrostatic chuck to be configured to receive a test wafer without a frame, in accordance with some embodiments.

FIG. 6 is a flowchart that illustrates a method for adapting an electrostatic chuck to be configured to receive a test wafer without a frame, in accordance with some embodiments.

FIG. 7 illustrates views of various stages of testing a frame form plasma process using an electrostatic chuck that is configured to receive a wafer without a frame, in accordance with some embodiments.

FIG. 8 is a flowchart that illustrates a method for testing a frame form plasma process using an electrostatic chuck that is configured to receive a wafer without a frame, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

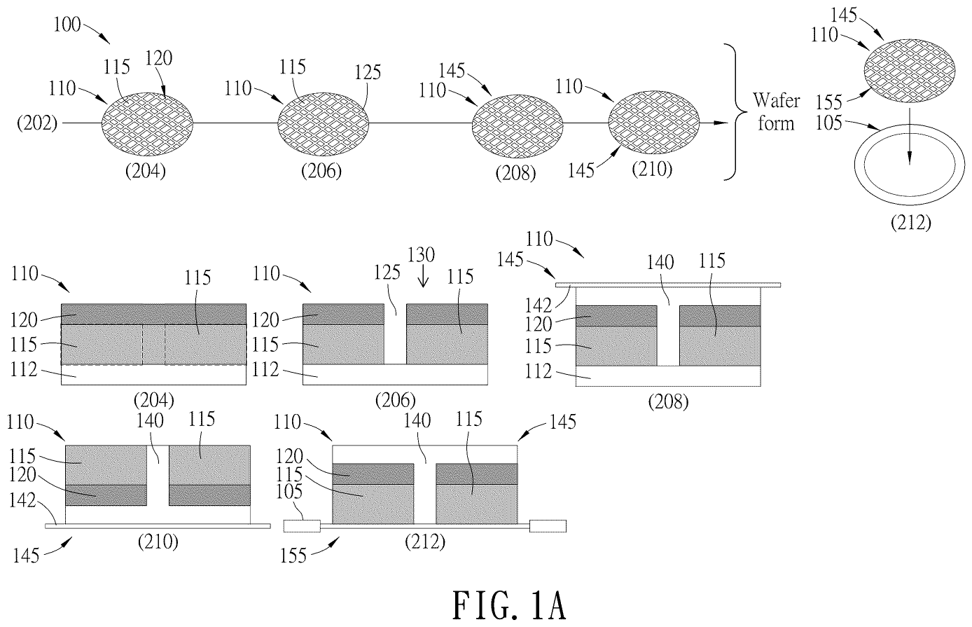

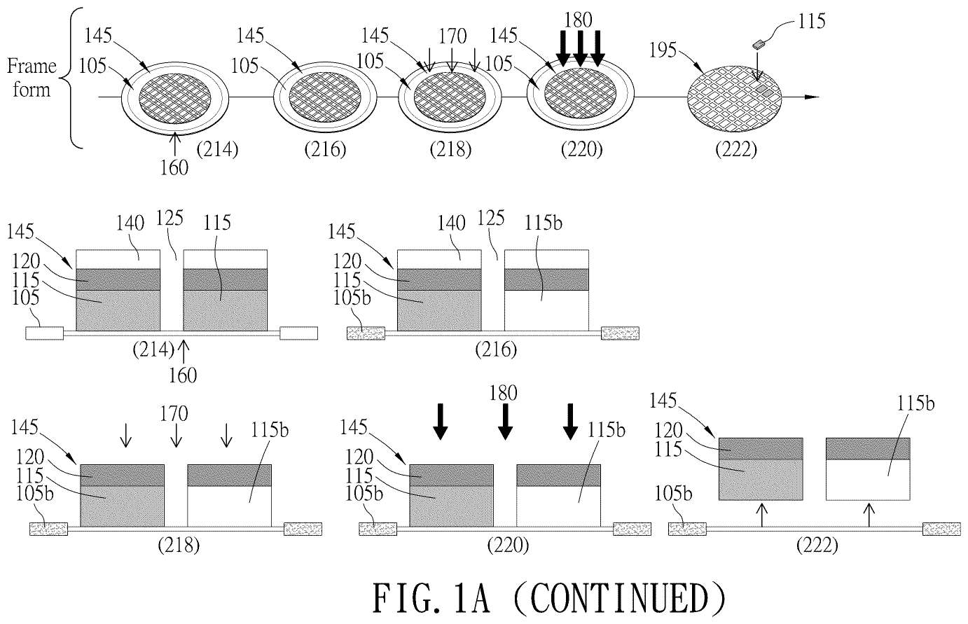

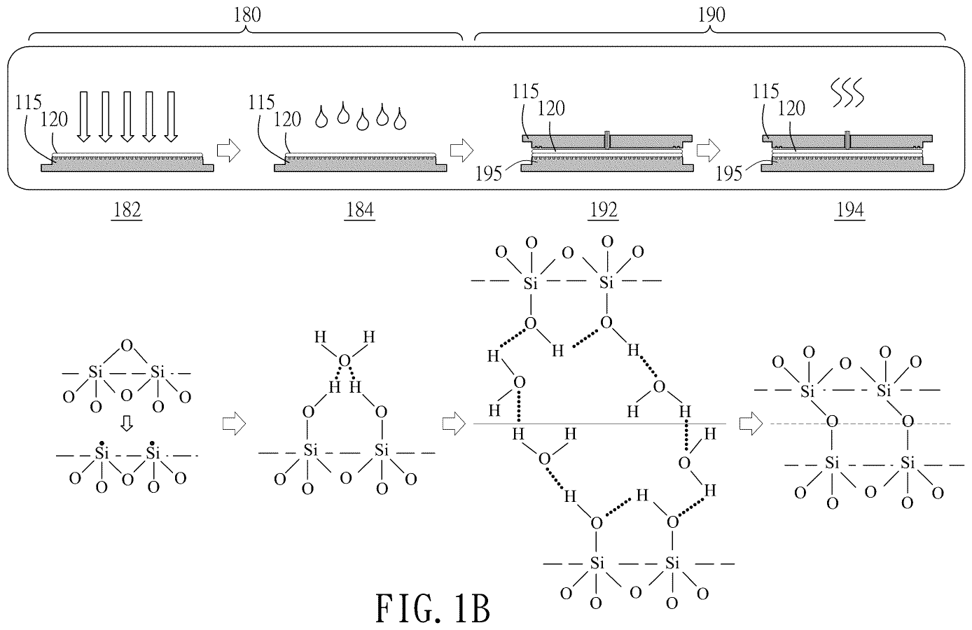

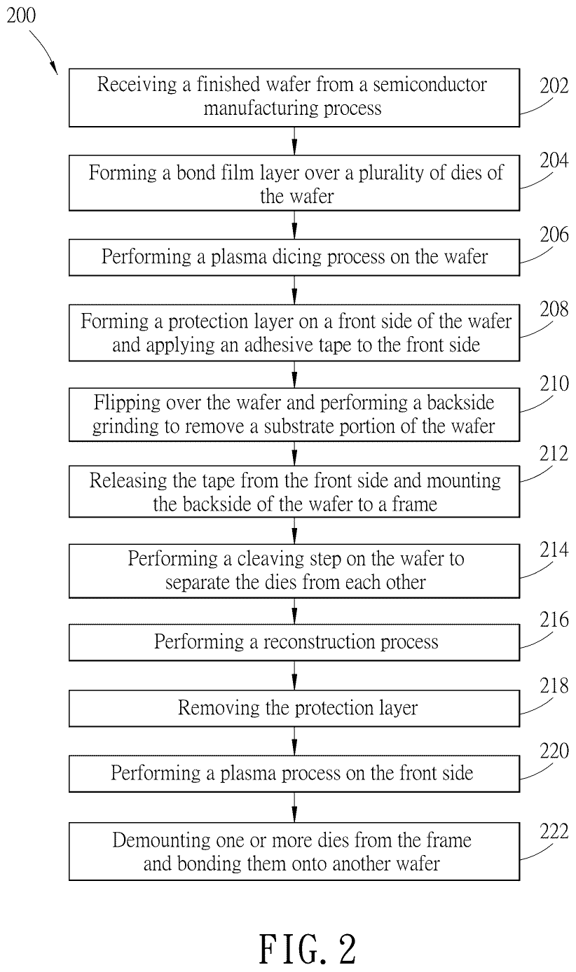

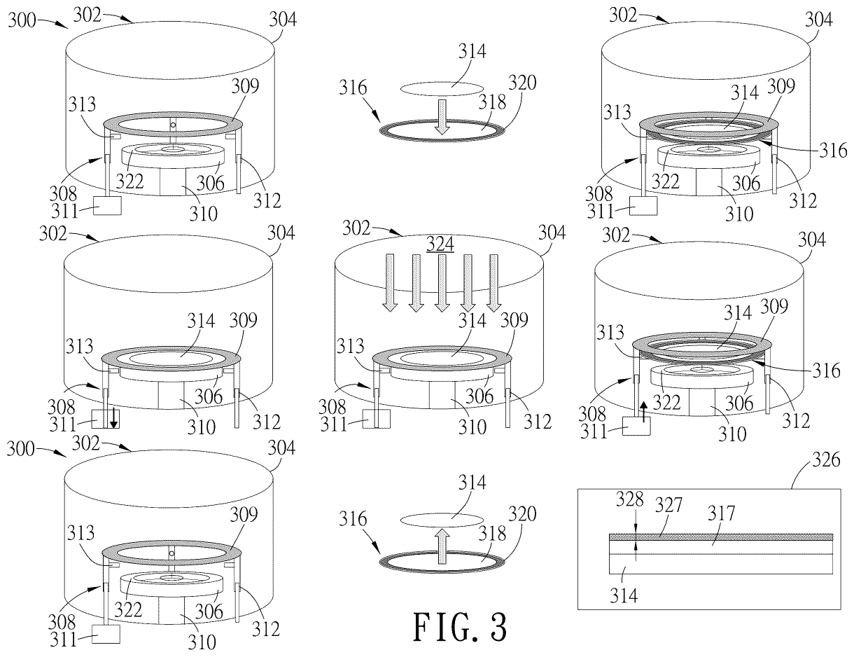

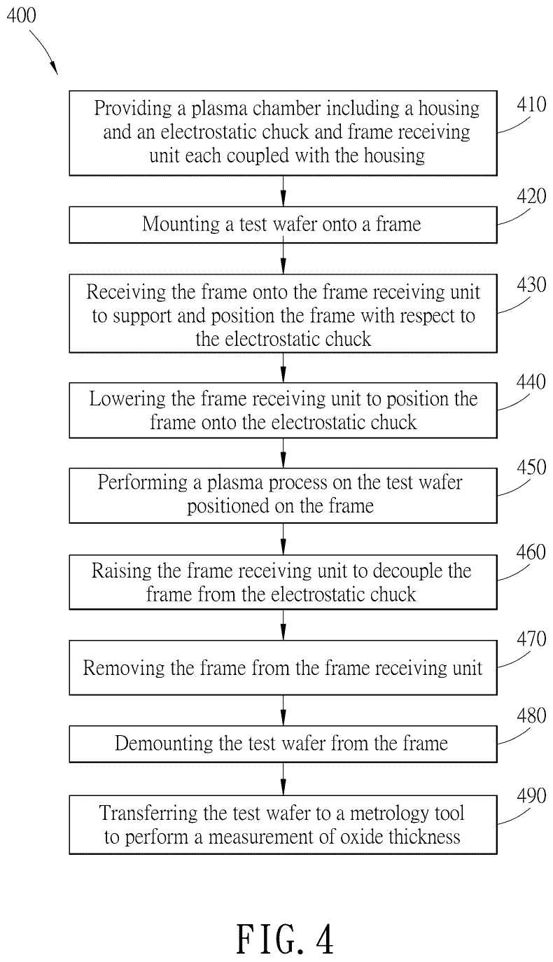

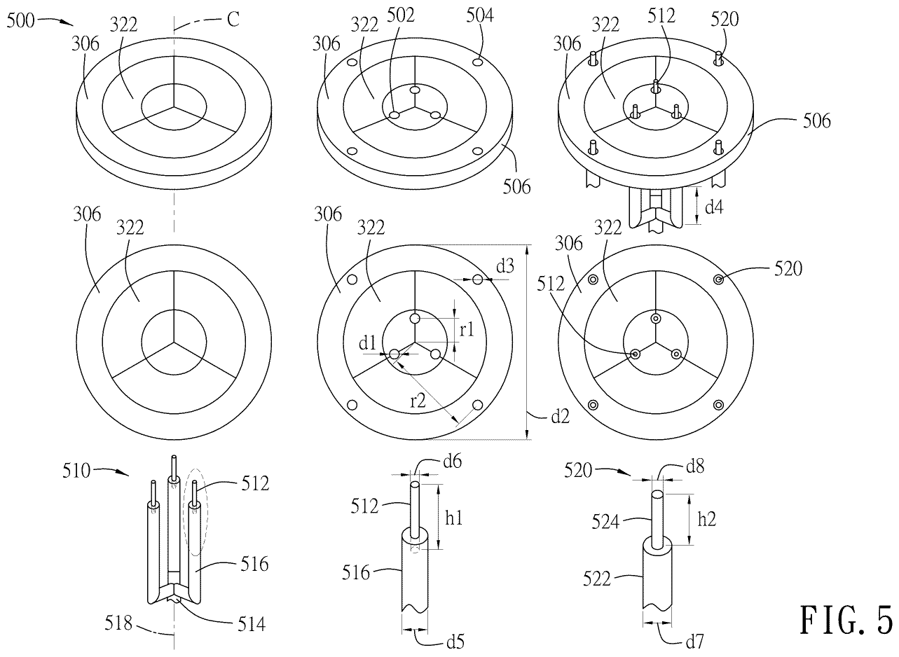

Embodiments of the present disclosure provide systems and methods associated with a frame form plasma process. An exemplary frame form plasma process to be used within a chip on wafer semiconductor packaging process is described in connection with FIGS. 1-2 of the present application. The plasma pre-treatment before die bonding enhances bonding strength, via native oxide growth, prevents corner non-bonding, and improves yield. With respect to the frame form plasma processes described herein, there is not a metrology tool for obtaining measurements (e.g., thickness of native oxide) on a frame form substrate (i.e., a substrate attached to a frame, such as wafer 110 attached to frame 105 in FIG. 1A). Thus, there is not an in-situ process available for determining certain key quality outcomes of the frame form plasma process (such as the activation process 180 applied to the one or more dies 115 in FIG. 1A). Instead, there is a need to validate performance of the frame form plasma process using periodic processing and evaluation of test wafers (e.g., blank wafers made from silicon). However, there is not, at present, any way to process a wafer using the frame form plasma process without mounting the wafer onto the frame. Thus, there is a need to process the frame form substrate using the frame form plasma process and then demount the substrate from the frame in order to obtain measurements on the substrate in wafer form (i.e., a substrate that is processed without being mounted on a frame). The latter scenario is the purpose of the system, process, and method described in connection with FIGS. 3-4 of the present application. Furthermore, it would be desirable in the industry to develop a system, process, and method to process a wafer using a frame form plasma process (i.e., within a plasma chamber used for the frame form plasma process) without mounting the wafer onto the frame. Exemplary solutions to the aforementioned industry need are presented herein in connection with FIGS. 5-8. This improvement toward processing substrates in wafer form improves monitoring of plasma treatment thickness and uniformity, improves throughput and precision and prevents contamination, via automation, and improves accuracy, such as meeting quality specifications.

FIGS. 1A and 1B illustrate views of various stages of a chip on wafer semiconductor packaging process 100, in accordance with some embodiments. FIG. 2 is a flowchart that illustrates a method 200 for a chip on wafer semiconductor packaging process, in accordance with some embodiments. It is understood that additional operations can be provided before, during, and after processes shown by FIGS. 1A-2, and some of the operations described below can be replaced or eliminated, for additional embodiments of the method. The order of the operations/processes is not limiting and may be interchangeable.

Referring to FIG. 1A and FIG. 2, at block 202, a finished wafer 110 is received from a semiconductor manufacturing process. The semiconductor manufacturing process can include any suitable manufacturing process that may include one or more additional processing steps, as disclosed herein, including, for example, at least one of a transistor process, such as a FinFET or nanosheet process, a memory process, such as an SRAM process, and the like. Likewise, the finished wafer 110 can include transistors, such as FinFET or nanosheet transistors, a memory chip, such as an SRAM chip, and the like.

A first portion of the process 100, beginning with the finished wafer 110, can be referred to as being in “wafer form” as labeled in FIG. 1A. The term “wafer form” indicates that the wafer 110 is processed without being mounted on a frame 105, an alternative setup which is described in more detail below. The wafer 110 can include a substrate 112 and a plurality of dies 115 disposed on the substrate 112 and physically integrated into the wafer 110.

At block 204 of the method 200, a bond film layer 120 is formed over the plurality of dies 115. In some embodiments, the bond film layer 120 undergoes a planarization/polishing process to make the bond film layer 120 uniform. For example, the polishing process can include a chemical mechanical polishing (CMP) process to control a thickness of the wafer 110 and/or to planarize a surface of the wafer 110. In some embodiments, the bond film layer 120 includes an oxide material (e.g., silicon oxide), and/or an oxynitride material (e.g., silicon oxynitride) for die to die or die to wafer bonding.

At block 206 of the method 200, a plasma dicing process 130 is performed on the wafer 110. In general, the plasma dicing process 130 is used to physically separate, at least partially, the plurality of dies 115 from each other. For example, after fabrication of the dies 115 on the substrate 112, the individual dies 115 may be separated from each other prior to packaging or being employed in other electronic circuitry (e.g., via a reconstruction process described in more detail below). The plasma dicing process 130 may use various suitable types of plasma etching techniques. For example, in some embodiments, after device fabrication, the wafer 110 is masked with a suitable mask material, leaving open areas between the dies 115. The masked wafer 110 is then processed using, for example, a reactive-gas plasma which etches the semiconductor material exposed between the dies 115, thereby creating channels 125 between the dies 115. The plasma etching may proceed partially or completely through the substrate 112. For example, as shown in FIG. 1A, a partial plasma etch is performed such that the channels 125 extend to the depth of the substrate 112 but not into and/or through the substrate 112. In such embodiments, the dies 115 remain attached to the substrate 112 until a further cleaving step is performed. In some other embodiments, the plasma etching step can cause the channels 125 to extend completely through the substrate 112 such that the dies 115 are separated at this stage.

At block 208 of the method 200, a protection layer 140 is formed on a front side 145 of the wafer 110. The protection layer 140 is formed over the bond film layer 120 of the dies 115 and over portions of the substrate 112 exposed within the channels 125. The protection layer 140 can be a polymer-based material layer having sufficient thickness to encapsulate and protect certain features on the wafer 110. For example, the polymer-based material can include plastic materials, epoxy resin, polybenzoxazole (PBO), polyimide (PI), polyethylene terephthalate (PET), polyvinyl chloride (PVC), polymethylmethacrylate (PMMA), polymer components doped with fillers including fiber, clay, ceramic, inorganic particles, other suitable polymers, or any combinations thereof.

Continuing at block 208, an adhesive tape 142 is applied to the front side 145 of the wafer 110. For example, the tape 142 may be applied to an upper surface of the protection layer 140 instead of to the dies 115, which can protect the dies 115 from any damage that may be caused by the taping.

At block 210 of the method 200, the wafer 110 is flipped over and backside grinding is performed to remove the substrate 112. The backside grinding can include various suitable types of planarization techniques.

At block 212 of the method 200, the tape 142 is released from the front side 145 and a backside 155 of the wafer 110 is mounted to an adhesive surface of the frame 105. In some embodiments, the process for releasing the tape 142 can include applying an ultraviolet (UV) light that affects the adhesive material and reduces the bonding strength between the tape 142 and the protection layer 140. The adhesive surface (or “tape”) can be any suitable adhesive material. With the backside 155 facing the frame 105, the front side 145 of the wafer 110, including the bond film layer 120, is facing away from the frame 105 and is exposed for further processing.

A second portion of the process 100, beginning with the mounting of the wafer 110 onto the frame 105, can be referred to as being in “frame form” as labeled in FIG. 1A. The term “frame form” indicates that the wafer 110 is processed while being mounted on the frame 105. At block 214 of the method 200, a cleaving step 160 is performed on the wafer 110 to separate the one or more dies 115 from each other. In some embodiments, the cleaving step 160 can be performed after the wafer 110 is mounted on the frame 105. For example, the cleaving step 160 can include stretching the adhesive surface of the frame 105 (e.g., by pushing the adhesive surface upwards as indicated by the arrow), which causes attachments between adjacent dies 115 to be put in tension until the dies 115 are physically separated from each other. In some embodiments, residual portions of the protection layer 140 may remain on sidewalls of the dies 115 after channels 125 are reformed by the cleaving step 160.

At block 216 of the method 200, a reconstruction process is performed. The reconstruction process includes testing die electrical properties to select certain dies 115 and regrouping the dies 115 to a second frame 105b. For example, the dies 115 on the second frame 105b are not necessarily the same dies 115 formed from the wafer 110 and may include dies 115b from other wafers.

At block 218 of the method 200, the protection layer 140 is removed from the dies 115 to expose the bond film layer 120. In some embodiments, removal of the protection layer 140 is performed by a cleaning process 170. For example, the cleaning process 170 can include a wet clean, dry clean, combinations thereof, or any other suitable cleaning process.

At block 220 of the method 200, an activation process 180 is performed on the front side 145. This particular activation process 180 is configured to be applied to the bond film layer 120 on the front side 145 of the dies 115 in order to improve bonding strength and to reduce corner non-bonding between the front side 145 and another wafer 195. Referring to FIG. 1B, the activation process 180 can include an N2 plasma treatment 182 for surface activation followed by a water rinse 184. For example, the N2 plasma treatment 182 creates dangling bonds by removing oxygen atoms from surface silicon of the silicon-containing bond film layer 120 as shown. The plasma treatment 182 can include evacuation of a plasma chamber holding the wafer 110 to any suitable vacuum pressure (e.g., approaching 70 mTorr), followed by a nitrogen (N2) purge (e.g., 2 cycles around 375 Torr). The plasma treatment 182 can further include introduction of process gas into the plasma chamber at any suitable flow rate (e.g., less than 500 standard cubic centimeters per minute (SCCM), such as about 50 SCCM). The plasma treatment 182 can further include utilizing an N2 plasma source with any suitable RF power (e.g., less than 100 W, such as 25 W low frequency and 60 W high frequency) applied for any suitable time period (e.g., just a few seconds up to several minutes). The plasma treatment 182 can further include a final N2 purge (e.g., back to the initial purge pressure of around 375 Torr). After the plasma treatment 182, the water rinse 184 causes the dangling bonds of the bond film layer 120 to react with OH groups in water to form an interface layer containing Si—OH and H2O molecules as shown. This interface layer can have a thickness between 5 angstroms and 20 angstroms.

At block 222 of the method 200, the one or more dies 115 are demounted from the frame 105 and bonded onto another wafer 195, as shown in FIG. 1A. An UV process may be performed to cause the adhesive surface of the frame 105 to lose the stickiness, thereby releasing the dies 115. In some embodiments, the bonding process 190 can be carried out using a bonding tool (which also may be referred to as a die press). Referring to FIG. 1B, the bonding process 190 can include positioning 192 a die 115 into contact with the wafer 195, via the front side 145 of the die 115. Initially, when the die 115 is brought into contact with the wafer 195, hydrogen bonding and other Van der Waals forces dominate the bonding interface, which enhances edge bond strength. The bonding process 190 can further include thermal annealing 194, which increases the bonding energy through the formation of covalent bonds between Si—O groups in each of the bond film layer 120 and the wafer 195. Based on formation of dangling bonds and the interface layer containing Si—OH and H2O molecules, via the activation process 180, the temperature of thermal annealing 194 can be lowered (e.g., from greater than 1000° C. to less than 400° C.). Also, based on the activation process 180, the edge bond strength between the die 115 and the wafer 195 is improved as a result of greater covalent bond formation, as described above.

In some embodiments, the wafer 195 may include a semiconductor substrate, such as a wafer, die, system on chip (SoC), or integrated system on chip (SoIC), among other examples. In some embodiments, the one or more dies 115 may include semiconductor dies (which also may be referred to herein as “chips”) that are to be attached to the semiconductor substrate. The one or more dies 115 may be arranged with respect to the wafer 195 according to a device layout that is to be formed using the die bonding process.

FIG. 3 illustrates views of various stages of testing a frame form plasma process 300, in accordance with some embodiments. FIG. 4 is a flowchart that illustrates a method 400 for testing a frame form plasma process, in accordance with some embodiments. It is understood that additional operations can be provided before, during, and after processes shown by FIGS. 3-4, and some of the operations described below can be replaced or eliminated, for additional embodiments of the method. The order of the operations/processes is not limiting and may be interchangeable.

Referring to FIG. 3 and FIG. 4, at block 410, a plasma chamber 302 is provided that includes a housing 304 and an electrostatic chuck 306 and frame receiving unit 308 coupled with the housing 304. The electrostatic chuck 306 is coupled with the housing 304 via a support 310 and may be held stationary within the housing 304. The frame receiving unit 308 can be operably coupled with the housing 304 and movable up and down (e.g., vertically) within the housing 304 (e.g., relative to the electrostatic chuck 306). In some embodiments, the frame receiving unit 308 includes a first element 312 configured to move up and down, a second element 313 coupled to the first element 312 and configured to support the frame 316, and a third element 309 attached to the first element 312 above the second element 313 and configured to cover a metal part of a frame 316 during plasma treatment. In some embodiments, the first element 312 can include a hollow cylinder, with a slit opening, that surrounds the electrostatic chuck 306. In other embodiments, the first element 312 can include a half cylinder that partially surrounds the electrostatic chuck 306. In other embodiments, the first element 312 can include a plurality of legs or rods that are circumferentially spaced apart around an outer diameter surface of the electrostatic chuck 306. In general, the frame receiving unit 308 can be driven by one or more linear actuators 311 to raise and lower the frame receiving unit 308 within the housing 304. For example, the one or more linear actuators 311 can be located outside the housing 304 as shown. The one or more linear actuators 311 can include various types such as mechanical linear actuators, electromechanical linear actuators, hydraulic linear actuators, pneumatic linear actuators, piezoelectric linear actuators, combinations thereof, and/or any other suitable type of linear actuator. The second element 313 can include a plurality of horizontal supports that are configured to support the frame 316. The drawings show an exemplary embodiment of the horizontal supports. In some embodiments, the horizontal supports can be integral with the first element 312. In other embodiments, the horizontal supports can be detachably connected to the first element 312. Collectively, an inner diameter defined by respective inner radial ends of the horizontal supports is greater than the outer diameter of the electrostatic chuck 306 to provide radial clearance between the horizontal supports and the electrostatic chuck 306 when the frame receiving unit 308 is lowered around the electrostatic chuck 306. The third element 309 can include a cover ring with an opening, or empty space, in the middle that can rest on the frame 316. In some embodiments, the third element 309 can function as a focus ring that improves process flow uniformity around the edge of the substrate.

At block 420 of the method 400, a test wafer 314 is mounted onto a frame 316. In some embodiments, the frame 316 is a solid disc without an opening, or empty space, in the middle. In some embodiments, the test wafer 314 may be a blank semiconductor wafer that is intended to be used for testing certain manufacturing processes. In some embodiments, the blank semiconductor wafer includes a native oxide layer 317, such as a silicon dioxide layer. Thus, the test wafer 314 may include only certain structures, features, and/or materials that are useful for testing the respective manufacturing processes. The frame 316 includes an adhesive surface 318 surrounded by a non-adhesive border 320 (e.g., made of metal). As shown, the adhesive surface 318 is sized and shaped to fit the size and shape of the test wafer 314. Likewise, the border 320 is sized and shaped to fit the size and shape of the frame receiving unit 308.

At block 430 of the method 400, the frame 316 is received onto the frame receiving unit 308 to support and position the frame 316 with respect to the electrostatic chuck 306. In some embodiments, the frame receiving unit 308 is kept stationary while the frame 316 is moved laterally through a vertical space defined between the second element 313 and the third element 309 of the frame receiving unit 308. The frame 316 is positioned onto the second element 313 to support and position the frame 316 on the frame receiving unit 308. In some embodiments, the frame 316 may be handled by a robotic handler that automates the loading process. For example, the robotic handler may transfer the frame 316 into the plasma chamber 302 from an adjacent equipment.

At block 440 of the method 400, the frame receiving unit 308 is lowered to position the frame 316 onto the electrostatic chuck 306. In some embodiments, the electrostatic chuck 306 is kept stationary while the frame receiving unit 308 is being lowered. As shown, the electrostatic chuck 306 fits between the horizontal supports of the second element 313 of the frame receiving unit 308. For example, there can be a radial clearance between the outer diameter surface of the electrostatic chuck 306 and respective inner radial ends of the horizontal supports to enable the frame receiving unit 308 to freely move up and down relative to the electrostatic chuck 306. The frame receiving unit 308 is lowered until a top surface 322 of the electrostatic chuck contacts the frame 316. Thereafter, as the frame receiving unit 308 continues moving downwards, the frame 316 is lifted off of the horizontal supports of the second element 313 and further downward movement eventually causes the third element 309 to contact a top side of the frame 316.

At block 450 of the method 400, an activation process 324 is performed on the test wafer 314 positioned on the frame 316. The activation process 324 can include the operations described above in connection with the activation process 180 associated with block 220 of the method 200, some operations can be replaced or eliminated, and/or additional operations can be provided. In some embodiments, the activation process 324 can include evacuation of the plasma chamber 302 to a gauge pressure below −300 mbar, such as −800 mbar to −500 mbar (which corresponds to an absolute pressure below about 700 mbar, such as about 200 mbar to about 500 mbar). In some embodiments, an interfacial layer 327 is formed on the native oxide layer 317 as a result of the activation process 324.

At block 460 of the method 400, the frame receiving unit 308 is raised to decouple the frame 316 from the electrostatic chuck 306. In some embodiments, the electrostatic chuck 306 is kept stationary while the frame receiving unit is being raised. As the frame receiving unit 308 moves upwards, a vertical space is created between the third element 309 and the frame 316. Thereafter, as the frame receiving continue moving upwards, the horizontal supports of the second element 313 contact a bottom side of the frame 316 and lift the frame 316 off of the electrostatic chuck 306.

At block 470 of the method 400, the frame 316 is removed from the frame receiving unit 308. In some embodiments, the frame receiving unit 308 is kept stationary while the frame 316 is lifted from the surface of the horizontal supports of frame receiving unit 308. In some embodiments, the frame 316 may be handled by a robotic handler that automates the unloading process.

At block 480 of the method 400, the test wafer 314 is demounted from the frame 316. At block 490 of the method 400, the test wafer 314 is transferred to a metrology tool 326 to perform a measurement of interfacial layer thickness 328. In some embodiments, the transfer of the test wafer 314 to the metrology tool 326 is an automated process. In some embodiments, the metrology tool 326 can perform one or more measurements on the test wafer 314 that indicate performance of the activation process 324. For example, the one or more measurements can include at least one of the measurement of interfacial layer thickness 328 (or an interfacial layer composition measurement) of a plasma-treated surface of the test wafer 314.

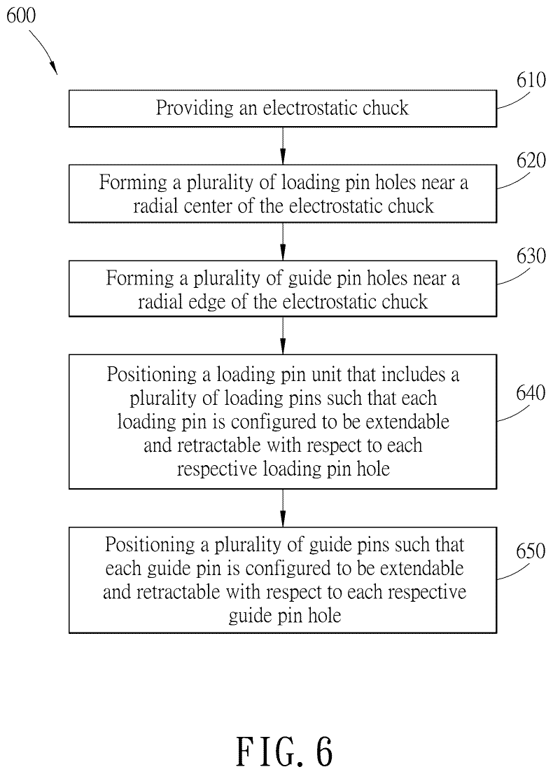

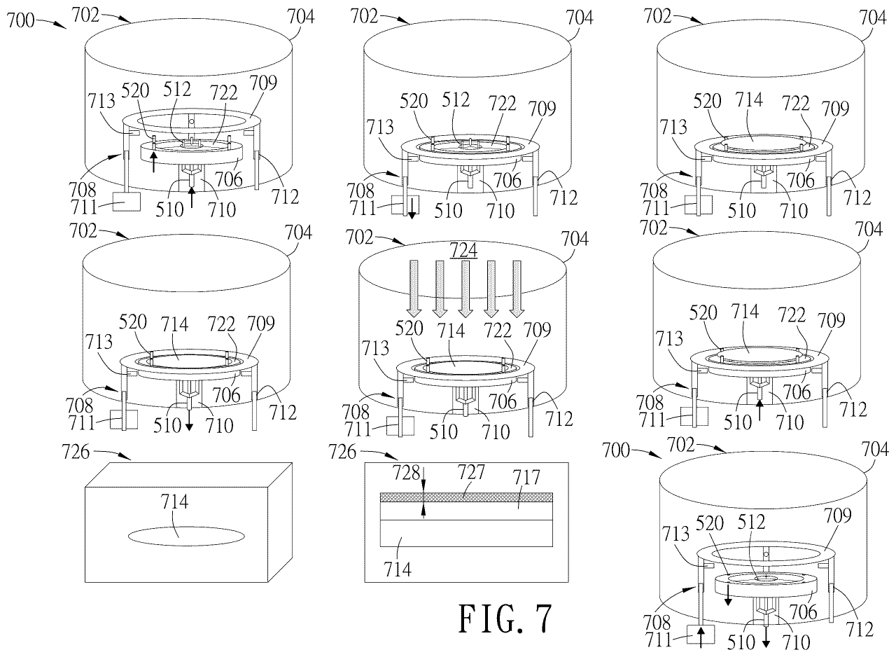

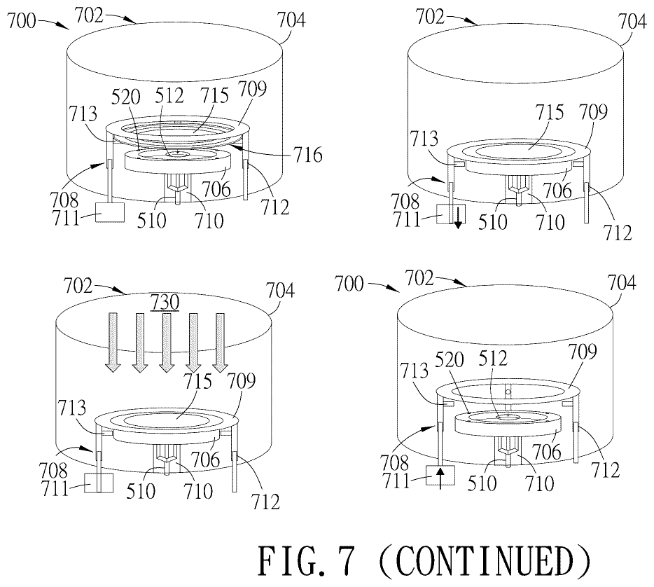

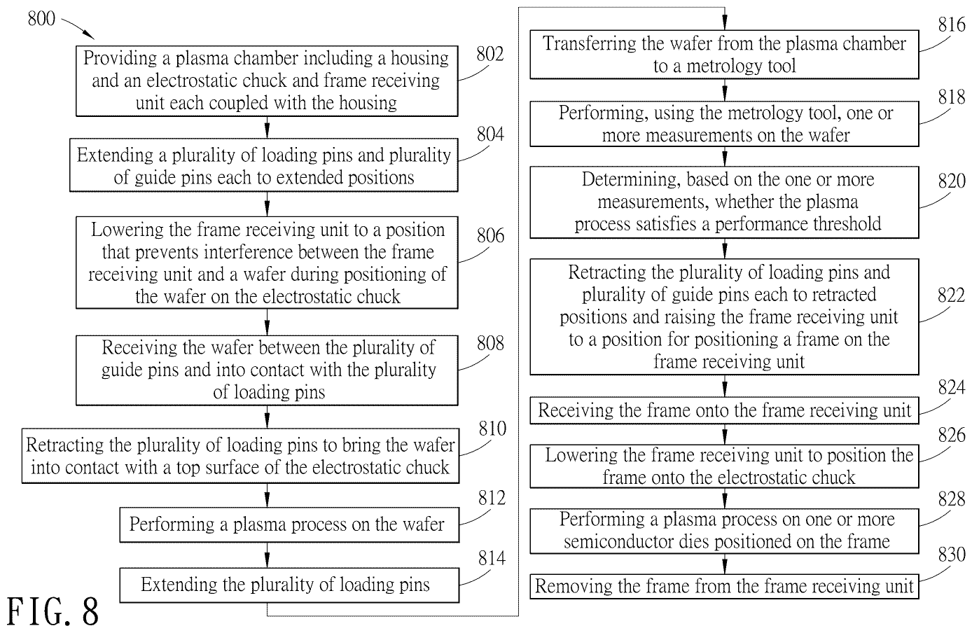

FIG. 5 illustrates views of various stages and associated components for adapting 500 the electrostatic chuck 306 to be configured to receive the test wafer 314 without the frame 316, in accordance with some embodiments. FIG. 6 is a flowchart that illustrates a method 600 for adapting the electrostatic chuck 306, in accordance with some embodiments. It is understood that additional operations can be provided before, during, and after processes shown by FIGS. 5-6, and some of the operations described below can be replaced or eliminated, for additional embodiments of the method. For example, aspects of FIGS. 5-6 can be combined in any suitable manner with FIGS. 3-4 and/or FIGS. 7-8. The order of the operations/processes is not limiting and may be interchangeable.

Referring to FIG. 5 and FIG. 6, at block 610, the electrostatic chuck 306 is provided. In some embodiments, the electrostatic chuck 306 is configured to receive the frame 316 that supports the test wafer 314, as shown in FIG. 3. However, without certain modifications, the electrostatic chuck 306 is not capable of receiving the test wafer 314 without the frame 316. In other words, the electrostatic chuck 306 needs to be adapted to enable processing of the test wafer 314 without the frame 316.

At block 620 of the method 600, a plurality of loading pin holes 502 are formed near a radial center of the electrostatic chuck 306. The electrostatic chuck 306 defines a center axis C through the radial center. In some embodiments, the plurality of loading pin holes 502 are through-holes defined in the electrostatic chuck 306 parallel to the center axis C. In some embodiments, the plurality of loading pin holes 502 are equidistant from the center axis C and/or equally spaced from each other circumferentially about the center axis C. In some embodiments, a radius r1 between the center axis C and each loading pin hole 502 can be within a range between 10 mm and 120 mm, such as 40 mm to 90 mm. Any suitable number of loading pin holes 502 can be implemented (e.g., 3 or more). In some embodiments, a diameter d1 of each loading pin hole 502 can be within a range between 1 mm and 10 mm, such as 3 mm to 6 mm. In some embodiments, a diameter d2 of the electrostatic chuck 306 can be within a range between 250 mm and 350 mm, such as 300 mm to 310 mm, such as 302 mm to 304 mm.

At block 630 of the method 600, a plurality of guide pin holes 504 are formed near an outer edge 506 of the electrostatic chuck 306. In some embodiments, the plurality of guide pin holes 504 are equidistant from the center axis C and/or equally spaced from each other circumferentially about the center axis C. In some embodiments, a radius r2 between the center axis C and each guide pin hole 504 can be within a range between 130 mm and 160 mm, such as 145 mm to 155 mm, such as 150.25 mm to 150.5 mm. Any suitable number of guide pin holes 504 can be implemented (e.g., 4 or more). In some embodiments, a diameter d3 of each guide pin hole 504 can be within a range between 10 mm and 20 mm, such as 12 mm to 17 mm.

At block 640 of the method 600, a loading pin unit 510, including a plurality of loading pins 512, is positioned such that each loading pin 512 is configured to be extendable and retractable with respect to each respective loading pin hole 502. The loading pin unit 510 can include a base portion 514 at a lower end that supports a plurality of loading pin portions 516 above the base portion 514. The plurality of loading pin portions 516 further support the plurality of loading pins 512 at an upper end. In some embodiments, the base portion 514 may be located at a radial center 518 of the loading pin unit 510, and the plurality of loading pin portions 516 can extend radially outward and upward from the base portion 514. A distance d4 that the plurality of loading pin portions 516 extends below the electrostatic chuck 306 can be between 2.2 cm and 4.5 cm. In some embodiments, the plurality of loading pin portions 516 are equidistant from the radial center 518 of the loading pin unit 510 and/or equally spaced from each other circumferentially about the radial center 518 of the loading pin unit 510, such that the layout of the plurality of loading pin portions 516, and the plurality of loading pins 512 attached thereto, match the layout of the plurality of loading pin holes 502, as described above. A diameter d5 of each loading pin portion 516 can be greater than a diameter d6 of each loading pin 512. In some embodiments, the diameter d6 of each loading pin 512 can be within a range between 1 mm and 10 mm, such as 2 mm to 5 mm. In some embodiments, a height h1 of each loading pin 512 above the respective loading pin portion 516 can be within a range between 1 cm and 4 cm, such as 1.5 cm to 3 cm. The plurality of loading pins 512 can be sized to fit through the plurality of loading pin holes 502 without resistance and/or to extend completely through the plurality of loading pin holes 502 from below the electrostatic chuck 306 to above the top surface 322 of the electrostatic chuck 306.

At block 650 of the method 600, a plurality of guide pins 520 are positioned such that each guide pin 520 is configured to be extendable and retractable with respect to each respective guide pin hole 504. Each guide pin 520 can include a base portion 522 at a lower end that supports an extension portion 524 at an upper end that extends upwards from the base portion 522. The base portion 522 can be sized to fit through the respective guide pin hole 504 without resistance. A diameter d7 of the base portion 522 can be greater than a diameter d8 of the extension portion 524, such that a space for the test wafer 314 to be centered between the plurality of guide pins 520 is greatest as the test wafer 314 first approaches the electrostatic chuck 306, and then the space narrows (tapers down) to improve the centering of the test wafer 314 via the plurality of guide pins 520, as described in more detail below. In some embodiments, the diameter d7 can be within a range between 10 mm and 20 mm, such as 12 mm to 17 mm. In some embodiments, the diameter d8 can be within a range between 5 mm and 20 mm, such as 10 mm to 15 mm. In some embodiments, a height h2 of each extension portion 524 above the respective base portion 522 can be within a range between 20 mm and 60 mm, such as 30 mm to 45 mm.

FIG. 7 illustrates views of various stages of testing a frame form plasma process 700 using an electrostatic chuck 706 that is configured to receive a wafer 714 without the frame 316, in accordance with some embodiments. FIG. 8 is a flowchart that illustrates a method 800 for testing a frame form plasma process using the electrostatic chuck 706, in accordance with some embodiments. It is understood that additional operations can be provided before, during, and after processes shown by FIGS. 7-8, and some of the operations described below can be replaced or eliminated, for additional embodiments of the method. The order of the operations/processes is not limiting and may be interchangeable.

Referring to FIG. 7 and FIG. 8, at block 802, a plasma chamber 702 is provided that includes a housing 704 and an electrostatic chuck 706 and frame receiving unit 708 coupled with the housing 704. In some embodiments, the electrostatic chuck 706 may be originally configured to process frame form substrates and adapted to process wafer form substrates using the method 600 according to embodiments of the present disclose. The electrostatic chuck 706 is coupled with the housing 704 via a support 710 and may be held stationary within the housing 704. The frame receiving unit 708 can be operably coupled with the housing 704 and movable up and down (e.g., vertically) within the housing 704 (e.g., relative to the electrostatic chuck 706). In some embodiments, the frame receiving unit 708 includes a first element 712 configured to move up and down, a second element 713 coupled to the first element 712 and configured to support the frame 716, and a third element 709 attached to the first element 712 above the second element 713 and configured to cover a metal part of a frame 716 during plasma treatment.

At block 804 of the method 800, a plurality of loading pins 512 and a plurality of guide pins 520 are each extended to extended positions. In some embodiments, extending the plurality of loading pins 512 includes moving the loading pin unit 510 upwards relative to the electrostatic chuck 706 in a direction parallel to the center axis C. The upwards movement of the loading pin unit 510 causes each loading pin 512 to move through the respective loading pin hole 502 in a direction facing away from a top surface 722 of the electrostatic chuck 706 to extend the upper end of the loading pin 512 above the top surface 722. When the plurality of loading pins 512 are in the extended position, the electrostatic chuck 706 is configured for loading and unloading the wafer 714 from the electrostatic chuck 706.

In some embodiments, extending the plurality of guide pins 520 includes moving the plurality of guide pins 520 upwards relative to the electrostatic chuck 706 in a direction parallel to the center axis C. The upwards movement of the plurality of guide pins 520 causes each guide pin 520 to move through the respective guide pin hole 504 in a direction facing away from the top surface 722 of the electrostatic chuck 706 to extend the upper end of the guide pin 520 above the top surface 722. When the plurality of guide pins 520 are in the extended position, the electrostatic chuck 706 is configured for radially centering the wafer 714 relative to the electrostatic chuck 706. In some embodiments, up and down movement of the loading pin unit 510 and the plurality of guide pins 520 may be controlled by a linear actuator, such as a piston. As described in more detail below, up and down movement of the loading pin unit 510 and the plurality of guide pins 520 may be independent from each other. However, in certain embodiments, the movements can be linked together.

At block 806 of the method 800, the frame receiving unit 708 is lowered to a position that prevents interference between the frame receiving unit 708 and a wafer 714 during positioning of the wafer 714 on the electrostatic chuck 706. In some embodiments, the frame receiving unit 708 is moved to be at or just above the electrostatic chuck 706 such that the upper ends of the plurality of loading pins 512 and plurality of guide pins 520 extend above the frame receiving unit 708, such that the frame receiving unit 708 does not interfere with a robotic handler (or arm) that handles loading and unloading of the wafer 714. In other words, the electrostatic chuck 706 is positioned to receive the wafer 714 from the robotic handler through the opening in the third element 709 of the frame receiving unit 708. Even though the frame receiving unit 708 may be positioned above the electrostatic chuck 706, the plurality of loading pins 512 extend above the electrostatic chuck 706, through the opening in the third element 709, and above the level of the third element 709 to provide clearance for the robotic handler to place the wafer 714 onto the plurality of pins 512 without contacting the robotic handler with any portion of the frame receiving unit 708.

At block 808 of the method 800, the wafer 714 is received between the plurality of guide pins 520 and into contact with the plurality of loading pins 512. In some embodiments, the wafer 714 may be a blank semiconductor wafer that is intended to be used for testing certain manufacturing processes. In some embodiments, the blank semiconductor wafer includes a native oxide layer 717, such as a silicon dioxide layer. In some embodiments, the wafer 714 may be handled by a robotic handler that automates the loading process. For example, the robotic handler may transfer the wafer 714 into the plasma chamber 702 from an adjacent equipment. After the wafer 714 is positioned onto the upper ends of the plurality of loading pins 512 and supported thereby, the robotic handler can be removed. As the wafer 714 is being positioned onto the upper ends of the plurality of loading pins 512, the wafer 714 is centered between and at a vertical level overlapping with the extension portion 524 of each loading pin 512. In this position, the wafer 714 is above a vertical level of the base portion 522 of each loading pin 512. As outlined above, because the extension portion 524 is smaller in diameter compared to the base portion 522, the space for the wafer 714 to be centered within is greatest in this position. Therefore, a first degree of centering is achieved at this point, and further centering may be achieved when the plurality of loading pins 512 are retracted.

At block 810 of the method 800, the plurality of loading pins 512 are retracted to bring the wafer 714 into contact with a top surface 722 of the electrostatic chuck 706. In some embodiments, retracting the plurality of loading pins 512 includes moving the loading pin unit 510 downwards relative to the electrostatic chuck 706 in a direction parallel to the center axis C. The downwards movement of the loading pin unit 510 causes each loading pin 512 to move through the respective loading pin hole 502 in a direction facing towards the top surface 722 of the electrostatic chuck 706 to retract the upper end of the loading pin 512 at or below the top surface 722. As the wafer 714 is being lowered towards the top surface 722, the wafer 714 reaches a vertical level at the interface of the extension portion 524 and base portion 522 of each loading pin 512. As outlined above, because the base portion 522 is smaller in diameter, the space for the wafer 714 to be centered within becomes narrower (tapers down) at the transition point and below, at the vertical level overlapping with the base portion 522, and a second more accurate degree of centering is achieved.

At block 812 of the method 800, an activation process 724 is performed on the wafer 714. The activation process 724 can include the operations described above in connection with the activation process 180 associated with the method 200, some operations can be replaced or eliminated, and/or additional operations can be provided. In some embodiments, the activation process 724 can include evacuation of the plasma chamber 702 to a gauge pressure below −300 mbar, such as −800 mbar to −500 mbar (which corresponds to an absolute pressure below about 700 mbar, such as about 200 mbar to about 500 mbar). In some embodiments, an interfacial layer 727 is formed on the native oxide layer 717 as a result of the activation process 724.

At block 814 of the method 800, the plurality of loading pins 512 are extended. Extension of the plurality of loading pins 512 can include the operations described above in connection with block 804, some operations can be replaced or eliminated, and/or additional operations can be provided. When the plurality of loading pins 512 are in the extended position, a vertical clearance is created between the wafer 714 and the top surface 722 to provide the robotic handler with access to pick up the wafer 714 from the electrostatic chuck 706.

At block 816 of the method 800, the wafer 714 is transferred from the plasma chamber 702 to a metrology tool 726. In some embodiments, the transfer of the wafer 714 to the metrology tool 726 is an automated process. After the wafer 714 is removed from the plasma chamber 702, the plasma chamber 702 is able to receive a frame 716 (e.g., for processing one or more semiconductor dies positioned thereon) or another wafer (e.g., a blank wafer for testing a frame form plasma process in process chamber 702). In some embodiments, the metrology tool 726 can be used to perform one or more measurements on the wafer 714 that indicate performance of the activation process 724, as described below.

At block 818 of the method 800, one or more measurements 728 are performed on the wafer 714 using the metrology tool 726. In some embodiments, the one or more measurements 728 can include a measurement of interfacial layer thickness 728 and/or an interfacial layer composition measurement of a plasma-treated surface of the wafer 714.

At block 820, the method 800 includes determining, based on the one or more measurements 728, whether the activation process 724 satisfies a performance threshold. For example, the performance threshold can include at least one of a uniformity (e.g., uniform thickness and/or uniform composition) or a contamination level of a plasma-treated surface of the wafer 714 resulting from the activation process 724.

At block 822 of the method 800, the plurality of loading pins 512 and plurality of guide pins 520 are each retracted to retracted positions, and the frame receiving unit 708 is raised to a position for positioning a frame 716 on the frame receiving unit 708. In some embodiments, the plurality of loading pins 512 and plurality of guide pins 520 are moved to, and maintained in, the retracted position to prevent interference with the frame 716. In some embodiments, retracting the plurality of loading pins 512 includes moving the loading pin unit 510 downwards relative to the electrostatic chuck 706 in a direction parallel to the center axis C. The downwards movement of the loading pin unit 510 causes each loading pin 512 to move through the respective loading pin hole 502 in a direction facing towards the top surface 722 of the electrostatic chuck 706 to retract the upper end of the loading pin 512 at or below the top surface 722. In some embodiments, retracting the plurality of guide pins 520 includes moving the plurality of guide pins 520 downwards relative to the electrostatic chuck 706 in a direction parallel to the center axis C. The downwards movement of the plurality of guide pins 520 causes each guide pin 520 to move through the respective guide pin hole 504 in a direction facing towards the top surface 722 of the electrostatic chuck 706 to retract the upper end of the guide pin 520 at or below the top surface 722. As described herein, up and down movement of the loading pin unit 510 and the plurality of guide pins 520 may be independent from each other. However, in certain embodiments, the movements can be linked together.

At block 824 of the method 800, the frame 716 is received onto the frame receiving unit 708.. At this step in the process, based on the activation process 724 being calibrated at block 820, one or more semiconductor dies 715 to undergo front side plasma treatment (e.g., according to block 220 of the method 200) are disposed on the frame 716. In some embodiments, the one or more semiconductor dies 715 may be the dies formed according to blocks 202-218 of the method 200. In some embodiments, the frame receiving unit 708 is kept stationary while the frame 716 is moved laterally through a vertical space defined between the second element 713 and the third element 709 of the frame receiving unit 708. The frame 716 is positioned onto the second element 713 to support and position the frame 716 on the frame receiving unit 708. In some embodiments, the frame 716 may be handled by a robotic handler that automates the loading process. For example, the robotic handler may transfer the frame 716 into the plasma chamber 702 from an adjacent equipment.

At block 826 of the method 800, the frame receiving unit 708 is lowered to position the frame 716 onto the electrostatic chuck 706. In some embodiments, the electrostatic chuck 706 is kept stationary while the frame receiving unit 708 is being lowered. As shown, the electrostatic chuck 706 fits between the horizontal supports of the second element 713 of the frame receiving unit 708. For example, there can be a radial clearance between the outer diameter surface of the electrostatic chuck 706 and respective inner radial ends of the horizontal supports to enable the frame receiving unit 708 to freely move up and down relative to the electrostatic chuck 706. The frame receiving unit 708 is lowered until a top surface 722 of the electrostatic chuck contacts the frame 716. Thereafter, as the frame receiving unit 708 continues moving downwards, the frame 716 is lifted off of the horizontal supports of the second element 713 and further downward movement eventually causes the third element 709 to contact a top side of the frame 716.

At block 828 of the method 800, an activation process 730 is performed on the one or more semiconductor dies 715 positioned on the frame 716. The activation process 730 can include the operations described above in connection with the activation process 180 associated with the method 200, some operations can be replaced or eliminated, and/or additional operations can be provided.

At block 830 of the method 800, the frame 716 is removed from the frame receiving unit 708. In order to remove the frame 716, the frame receiving unit 708 is raised back to the position in block 824 as described above. After the frame 716 is removed from the plasma chamber 702, the one or more semiconductor dies 715 can be demounted from the frame 716 and further processed and/or bonded onto another wafer, such as described in connection with FIGS. 1A-2.

Any of the various system processes and methods described herein can be carried out by a controller. The controller can be a workstation computer, a desktop computer, a laptop computer, a tablet computer, or any other type of computing device comprising one or more software products that are capable of controlling processes (e.g., based on input/output of certain operational parameters), receiving process feedback, receiving test result data, performing process adjustments, and/or other software-related control schemes. In some embodiments, the controller includes a processor and a memory. The processor may include a central processing unit (CPU), a graphics processing unit (GPU), a microprocessor, and/or other processing units or components. The memory may be implemented as computer-readable storage media (CRSM), which may be any available physical media accessible by the processor to execute instructions stored on the memory. The memory may be capable of storing various computer readable instructions for performing certain operations described herein (e.g., operations of the controller). The instructions, when executed by the processor, may cause certain operations described herein to be performed. The controller can be communicatively coupled with and control the process chamber 302, 702 and metrology tool 326, 726 and various equipment (e.g., robot handler, electrostatic chuck, loading pin unit, guide pins, chuck support, frame receiving unit, plasma sources, gas sources, valves, sensors, and other equipment) associated with the process chamber 302, 702 and metrology tool 326, 726 to implement one or more aspects of the methods herein.

Embodiments of the present disclosure provide systems and methods associated with a frame form plasma process. In some embodiments, a method includes providing a plasma chamber including an electrostatic chuck and a frame receiving unit configured to support and position a frame with respect to the electrostatic chuck, the frame including an adhesive surface that is configured to receive a plurality of semiconductor dies for plasma processing, wherein the electrostatic chuck is configured to receive, at different times, the frame or a wafer without the frame; positioning the wafer onto the electrostatic chuck without the frame; performing the activation process on a front side of the wafer; transferring the wafer from the plasma chamber to a metrology tool; performing, using the metrology tool, one or more measurements on the wafer; determining, based on the one or more measurements, whether the activation process performed on the wafer using the plasma chamber satisfies a performance threshold; positioning the frame, including the plurality of semiconductor dies disposed thereon, onto the electrostatic chuck; and performing, based on determining that the activation process satisfies the performance threshold, the plasma processing on a front side of the plurality of semiconductor dies.

In some embodiments, a plasma chamber includes a housing; an electrostatic chuck operably coupled with the housing and configured to receive, at different times, a frame or a wafer without the frame, the frame including an adhesive surface that is configured to receive a plurality of semiconductor dies for plasma processing; and a frame receiving unit operably coupled with the housing and configured to support and position the frame with respect to the electrostatic chuck, wherein the electrostatic chuck and frame receiving unit are relatively movable between: a first position for positioning the frame on the frame receiving unit; and a second position that prevents interference between the frame receiving unit and the wafer during positioning of the wafer on the electrostatic chuck.

In some embodiments, a method includes providing a plasma chamber including an electrostatic chuck and a frame receiving unit configured to support and position a frame with respect to the electrostatic chuck, the frame including an adhesive surface that is configured to receive a plurality of semiconductor dies for plasma processing; adapting the electrostatic chuck to be configured to receive a wafer without the frame; positioning the wafer onto the electrostatic chuck without the frame; performing the activation process on a front side of the wafer; and transferring the wafer from the plasma chamber to a metrology tool for performing one or more measurements on the wafer to determine whether the activation process performed on the wafer using the plasma chamber satisfies a performance threshold.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
providing a plasma chamber including an electrostatic chuck and a frame receiving unit configured to support and position a frame with respect to the electrostatic chuck, the frame including an adhesive surface that is configured to receive a plurality of semiconductor dies for plasma processing, wherein the electrostatic chuck is configured to receive, at different times, the frame or a wafer without the frame;
positioning the wafer onto the electrostatic chuck without the frame;
performing the activation process on a front side of the wafer;
transferring the wafer from the plasma chamber to a metrology tool;
performing, using the metrology tool, one or more measurements on the wafer;
determining, based on the one or more measurements, whether the activation process performed on the wafer using the plasma chamber satisfies a performance threshold;
positioning the frame, including the plurality of semiconductor dies disposed thereon, onto the electrostatic chuck; and
performing, based on determining that the activation process satisfies the performance threshold, the plasma processing on a front side of the plurality of semiconductor dies.

2. The method of claim 1, further comprising positioning the plurality of semiconductor dies onto the adhesive surface of the frame.

3. The method of claim 1, further comprising periodically repeating the activation process on the wafer and the one or more measurements to determine whether the activation process satisfies the performance threshold before continuing the plasma processing of the plurality of semiconductor dies.

4. The method of claim 1, wherein the performance threshold includes at least one of a uniformity or a contamination level of a plasma-treated surface of the wafer.

5. The method of claim 1, wherein the one or more measurements include at least one of an interfacial layer thickness measurement or an interfacial layer composition measurement of a plasma-treated surface of the wafer.

6. The method of claim 1, wherein the activation process comprises an N₂ plasma treatment and a water rinse.

7. A plasma chamber, comprising:
a housing;
an electrostatic chuck operably coupled with the housing and configured to receive, at different times, a frame or a wafer without the frame, the frame including an adhesive surface that is configured to receive a plurality of semiconductor dies for plasma processing; and
a frame receiving unit operably coupled with the housing and configured to support and position the frame with respect to the electrostatic chuck, wherein the electrostatic chuck and frame receiving unit are relatively movable between:
a first position for positioning the frame on the frame receiving unit; and
a second position that prevents interference between the frame receiving unit and the wafer during positioning of the wafer on the electrostatic chuck.

8. The plasma chamber of claim 7, wherein the electrostatic chuck comprises:
a plurality of loading pin holes near a radial center of the electrostatic chuck; and
a loading pin unit including a plurality of loading pins, wherein each loading pin is configured to be extendable and retractable with respect to each respective loading pin hole.

9. The plasma chamber of claim 8, wherein the electrostatic chuck further comprises:
a plurality of guide pin holes near an outer edge of the electrostatic chuck; and
a plurality of guide pins, wherein each guide pin is configured to be extendable and retractable with respect to each respective guide pin hole.

10. The plasma chamber of claim 9, wherein, when the electrostatic chuck is to receive the wafer without the frame, the plurality of loading pins are moved between an extended position and a retracted position to load and unload the wafer from the electrostatic chuck and the plurality of guide pins are maintained in an extended position to radially center the wafer relative the electrostatic chuck, and wherein, when the electrostatic chuck is to receive the frame, the plurality of loading pins are maintained in the retracted position and the plurality of guide pins are maintained in a retracted position to prevent interference with the frame.

11. A method, comprising:
providing a plasma chamber including an electrostatic chuck and a frame receiving unit configured to support and position a frame with respect to the electrostatic chuck, the frame including an adhesive surface that is configured to receive a plurality of semiconductor dies for plasma processing;
adapting the electrostatic chuck to be configured to receive a wafer without the frame;
positioning the wafer onto the electrostatic chuck without the frame;
performing the activation process on a front side of the wafer; and
transferring the wafer from the plasma chamber to a metrology tool for performing one or more measurements on the wafer to determine whether the activation process performed on the wafer using the plasma chamber satisfies a performance threshold.

12. The method of claim 11, wherein adapting the electrostatic chuck comprises forming a plurality of loading pin holes near a radial center of the electrostatic chuck; and positioning a loading pin unit within the plasma chamber, the loading pin unit including a plurality of loading pins such that each loading pin is configured to be extendable and retractable with respect to each respective loading pin hole.

13. The method of claim 12, wherein adapting the electrostatic chuck further comprises forming a plurality of guide pin holes near an outer edge of the electrostatic chuck; and positioning a plurality of guide pins within the plasma chamber such that each guide pin is configured to be extendable and retractable with respect to each respective guide pin hole.

14. The method of claim 13, wherein the frame receiving unit of the plasma chamber is positioned radially outside the plurality of guide pins.

15. The method of claim 13, wherein positioning the wafer onto the electrostatic chuck comprises extending the plurality of loading pins to an extended position for loading and unloading the wafer from the electrostatic chuck; extending the plurality of guide pins to an extended position for radially centering the wafer relative the electrostatic chuck; lowering the frame receiving unit to a position that prevents interference between the frame receiving unit and the wafer during positioning of the wafer on the electrostatic chuck; receiving the wafer between the plurality of guide pins and into contact with the plurality of loading pins to support the wafer with the plurality of loading pins; and retracting the plurality of loading pins to bring the wafer into contact with a top surface the electrostatic chuck.

16. The method of claim 15, wherein positioning the wafer onto the electrostatic chuck further comprises lowering the frame receiving unit from a first height above a support surface of the electrostatic chuck to a second height at or below the support surface of the electrostatic chuck, wherein the frame receiving unit is configured to be moved without interference between the plurality of guide pins and the frame receiving unit.

17. The method of claim 13, further comprising:
performing, based on determining that the activation process performed on the wafer using the plasma chamber satisfies the performance threshold, the plasma processing of the plurality of semiconductor dies, including:
positioning the plurality of semiconductor dies onto the adhesive surface of the frame;
positioning the frame onto the electrostatic chuck; and
performing the activation process on a front side of the plurality of semiconductor dies.

18. The method of claim 17, wherein positioning the frame onto the electrostatic chuck comprises maintaining the plurality of loading pins in a retracted position; and maintaining the plurality of guide pins in a retracted position to prevent interference with the frame.

19. The method of claim 17, further comprising bonding one or more dies of the plurality of semiconductor dies to a semiconductor substrate.

20. The method of claim 11, wherein the wafer is a blank wafer.
